(19) United States
(12) Patent Application Publication
(10) Pub. No.: US 2021/0210644 A1
(43) Pub. Date: Jul. 8, 2021

(54) SEMI TRANSPARENT PHOTOVOLTAIC DEVICE WITH OPTIMIZED COLLECTOR GRID

(71) Applicant: Garmin Switzerland GmbH, Schaffhausen (CH)

(72) Inventors: Eric J. Betschitch, Saint-Chamas (FR); Oliver R. F. Gagliano, Marseille (FR); Emilie Bialic, Alleins (FR); Brice Arrazat, Rousset (FR)

(21) Appl. No.: 17/209,967

(22) Filed: Mar. 23, 2021

Related U.S. Application Data
(63) Continuation of application No. PCT/IB2019/057900, filed on Sep. 19, 2019.

(30) Foreign Application Priority Data
Sep. 24, 2018 (FR) FR 18 00991

(51) Int. Cl. H01L 31/02; H01L 31/0747; H01L 31/0224

(52) U.S. Cl. CPC H01L 31/02008; H01L 31/022491; H01L 31/0747

(57) ABSTRACT

A semitransparent photovoltaic device comprising: a plurality of active photovoltaic areas including a transparent substrate, a front electrode, an absorber including one or more thin photoactive layers, and a rear electrode; a transparency area separating at least two of the active photovoltaic areas; and a collection grid. The collection grid includes a metallic contact layer and a plurality of VIAs between the front electrode and the metallic contact layer, wherein the VIAs are randomly distributed within the active photovoltaic area.

### RELATED APPLICATIONS

The present application is a continuation of, and claims priority benefit to, co-pending international application entitled, “SEMI-TRANSPARENT PHOTOVOLTAIC DEVICE WITH AN OPTIMISED ELECTRICAL CURRENT-COLLECTING GRID,” International Application No. PCT/IB2019/057900, filed Sep. 19, 2019, which claims priority to French Patent Application No. 18/00991, filed Sep. 24, 2018. Each of the above-referenced applications are hereby incorporated by reference into the current application in their entirety.

### BACKGROUND

A thin-film photovoltaic cell is composed of at least:
a substrate, which can be flexible, e.g., a polymer, or rigid, e.g., glass;
a first transparent electrically conductive electrode, for example made of zinc oxide doped with aluminum (ZnO:Al);
a second generally metallic electrically conductive electrode, for example made of molybdenum (Mo);
an absorber constituting the photoactive part, which may be composed of a single layer or of a stack of layers based, for example, on amorphous silicon or an alloy of copper, indium, galium, and selenium, hereinafter called CIGS;
optionally one or more buffer layers, for example made of cadmium sulphide (CdS) in the case of an absorber consisting of CIGS;
optionally one or more barrier layers;

The thickness of each thin layer varies from a few hundred nanometers to a few microns. The stacking order of the thin layers is determined by the thin film technology in question.

A photovoltaic device designates any type of photovoltaic cell or module. Photovoltaic modules are composed of a plurality of photovoltaic cells, all of which interconnected according to a series, parallel, parallel-series, or series-parallel architecture. A photovoltaic device is composed, for example, of a plurality of photovoltaic cells that are arranged in series in order to increase the electric voltage at the terminals of the module. Methods are known for placing photovoltaic cells in series through successive stages of isolation and interconnection of the various constituent layers as described in document EP 0500451 B 1.

The transparency or semitransparency of photovoltaic devices enable said devices to be integrated more aesthetically into products, particularly into everyday consumer electronic devices such as connected watches. This transparency can be achieved by means of etching, lithography, and/or laser ablation processes. In general, a semitransparent thin-film photovoltaic cell comprises a plurality of opaque photovoltaic active areas that are separated by transparency areas. The photovoltaic areas (and, respectively, transparency areas) can be of any shape. The critical dimension of said shape is then defined as being the smallest of the sizes characterizing it. This is, for example, a side for a square, the width for a rectangle, the height for a triangle. For example, in the case of a photovoltaic strip, the critical dimension, denoted CD, corresponds to the width of said strip. When a transparent, homogeneous appearance is desired (i.e., when it is not desired for the opaque areas to be distinguished with the naked eye from the transparency areas), the critical dimension of the photovoltaic strips is preferably less than 200 microns.

In a known embodiment, the active photovoltaic areas and the transparency areas are organized in networks of elementary, linear, circular, or polygonal geometric structures. The transparency of the photovoltaic cell is then a function of the surface fraction that is occupied by the active photovoltaic areas.

Patent WO 2014/188092 A1 presents an advantageous embodiment of a semitransparent thin-film photovoltaic monocell. Nevertheless, the electrical performance of these semitransparent cells is degraded compared to a solid cell (i.e., without a transparency area) of equivalent surface area. It is known to those skilled in the art to add a collection grid in order to facilitate the collection of the electric current. This electrically conductive collection grid is placed either in contact with the transparent electrode or in contact with the absorber. For example, patent WO 2014/188092 A1 describes a particular architecture of an improved collection grid that is adapted to a method which is implemented in order to achieve transparency. The establishment of electrical contact between the collection grid and the conductive transparent electrode of the thin-film photovoltaic cell is achieved by means of particular structures that are described in the aforementioned patent and referred to as VIAs. The set composed of the collection grid and the VIAs forms the improved collection grid.

However, VIAs are necessarily metallic (made of aluminum, silver, or molybdenum, for example) due to the required electrical conductivity, and they are therefore reflective. Due to their size and orderly placement, the network they form is generally perceptible to the naked eye. Said network of VIAs then causes visual discomfort.

It might be possible to reduce the dimensions of the VIAs. However, the process costs then become prohibitive. Indeed, in order to reduce the dimensions of VIAs to less than a few microns, it would then be necessary to equip production lines with new-generation photolithography machines that are 100 times more expensive than standard photolithography machines.

The present invention seeks to resolve the dual problem of the cost of manufacture and the invisibility of VIAs within semitransparent photovoltaic modules.

### SUMMARY

Embodiments of the present invention relates to a semitransparent thin-film photovoltaic device that is provided with an electric current-collecting grid, the architecture of which is optimized to minimize the visual impact of said collection grid. Various embodiments propose an architecture of VIAs that are arranged so as to impart a quasi-uniformity in transparency to the photovoltaic device while maximizing the collection of electric charges, all while minimizing the manufacturing cost of said device. It is another object of the invention to propose a method for placing VIAs according to the constraints of the targeted architecture.

In one embodiment, a semitransparent photovoltaic device comprises a plurality of active photovoltaic areas including a transparent substrate, a front electrode, an absorber including one or more thin photoactive layers, and a rear electrode; a transparency area separating at least two of the active photovoltaic areas; and a collection grid. The collection grid includes a metallic contact layer and a plurality of VIAs between the front electrode and the metallic contact layer, wherein the VIAs are randomly distributed within the active photovoltaic area. The VIAs are randomly distributed while respecting predetermined electrical and optical constraints so as to avoid the presence of VIA gaps and clusters.

In one example, the critical dimension CD_{PV} of the active photovoltaic areas is between 1 μm and 100 μm.

According to one embodiment, the critical dimension CD_{T} of the transparency areas is less than 1 mm.

According to one embodiment, the surface area of a VIA is between 15 μm² and 50 μm².

According to one embodiment, the maximum distanceD_{VIA_max} between two VIAs is equal to 1000 μm, and the minimum distance D_{VIA_min} between two VIAs is equal to 5 μm.

According to one embodiment, the density d of the VIAs is less than 70 VIAs/mm² and greater than 10 VIAs/mm².

According to one embodiment, all of the VIAs are centered within the active photovoltaic areas.

In practice, one of the photoactive layers of the absorber can be composed of amorphous silicon.

Various embodiments provide for random placement of VIAs that enables the semitransparent photovoltaic device described above to be manufactured and comprises the following steps:
Step A: Selection of an eligible active photovoltaic area for the placement of VIAs according to predefined criteria;
Step B: Definition of the electrical and optical constraints for the placement of VIAs;
Step C: Initialization of the placement of the VIAs (8) within the eligible photovoltaic area defined in step A;
Step D: Placement of the following VIAs by means of an iterative process within said eligible area defined in step A;
Step E: Return to step A as long as one or more eligible active photovoltaic area(s) not already selected previously does not contain VIAs. According to one embodiment of the method, step A further comprises the following sub-steps:
Step A1: Selection of an active photovoltaic area without a VIA that was not already selected previously;
Step A2: Selection of eligibility criteria for active photovoltaic areas for VIA placement;
Step A3: Validation of the selection for the placement of VIAs in this area, which becomes an eligible active photovoltaic area.

According to one embodiment of the method, step B further comprises the following sub-steps:
Step B: Definition of the constraints for the placement of VIAs, namely:
   Step B1: Definition of the electrical constraints according to the architecture of the photovoltaic areas through selection of the initial values D_{VIA_max_0}=1000 μm and D_{VIA_min_0}=1 μm or values such as D_{VIA_max}<1000 μm and D_{VIA_min}>1 μm, while verifying that D_{VIA_max}>D_{VIA_mm}.
   Step B2: Definition of the optical constraints according to the architecture of the photovoltaic areas through selection of the initial value of the density d₀=70 VIAs/mm² or through selection of a density value of less than 70 VIAs/mm².

According to one embodiment of the method, step C further comprises the following sub-steps:
Step C0: Selection of the end of the eligible active photovoltaic area and the value of the distance D_{EX}between said end and the first VIA of said area, referred to as the inter-VIA-end distance.
Step C1: Selection of the first VIA placement area Z₁, this area being determined by the inter-VIA-end distance D_{EX} and by the maximum inter-VIA distance D_{VIA_max}.; the first area being between DE_{X} and (D_{EX}+D_{VIA_max}).
Step C2: Random placement P₁ of the first VIA in the first VIA placement areas Z₁.

According to one embodiment of the method, step D further comprises the following sub-steps:
Step D1: Definition of the i^{th} VIA placement area, denoted Zᵢ, as a function of the placement constraints of the VIAs and the placement of the (i-1)th VIA placed in the area P₍ᵢ₋₁₎, as a function of D_{VIA_max} and D_{VIA_min}.
Step D2: Random placement Pᵢ of the i^{th} VIA in the i^{th} VIA placement area, denoted Zᵢ, until all VIAs have been placed in the active PV area selected in step A. Advantageously, the random placement within the active photovoltaic areas follows a discrete or continuous uniform law, a normal law, a Poisson law, or any type of law describing a random process.

### BRIEF DESCRIPTION OF THE DRAWING FIGURES

FIG. 1A is a sectional view of a known thin-film photovoltaic stack.

FIG. 1B is a top view of the photovoltaic stack of FIG. 1A within which a plurality of thin layers have been etched in places in order to form transparency areas and active photovoltaic areas.

FIG. 1C is a top view of the stack of FIG. 1B to which the VIA-type contact areas have been added.

FIG. 1D is a sectional view along the direction X of FIG. 1C.

FIG. 1E is a sectional view from FIG. 1D to which an isolation layer has been added.

FIG. 1F is a sectional view taken from FIG. 1E to which a metallic contact layer has been added.

FIG. 2A is an illustration of the visual rendering of VIAs that have been placed randomly and create visual defects for a known semitransparent photovoltaic module that is intended to be integrated into a watch glass.

FIG. 2B is an illustration of the visual rendering of VIAs that have been placed randomly and without visual defects for a semitransparent photovoltaic module that is the subject of the invention and intended to be integrated into a watch glass.

FIGS. 3A to 3F are views of the intermediate photovoltaic modules obtained according to different steps of a first example of the method according to the invention.

FIGS. 4A to 4J are views of the intermediate photovoltaic modules obtained according to different steps of a second example of the method according to the invention.

FIG. 5 is a photograph of a semitransparent photovoltaic module according to the invention that is designed to be integrated into a watch.

### DETAILED DESCRIPTION

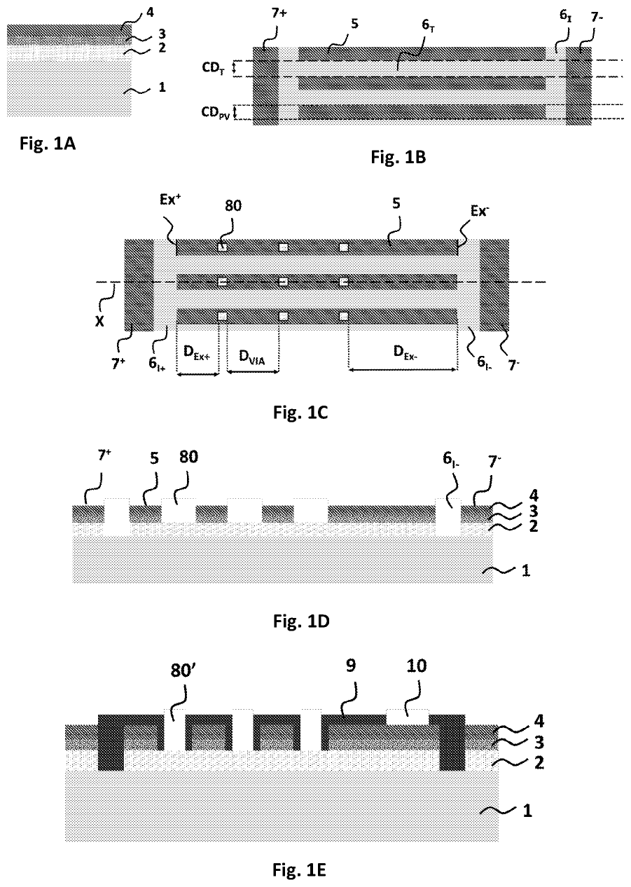

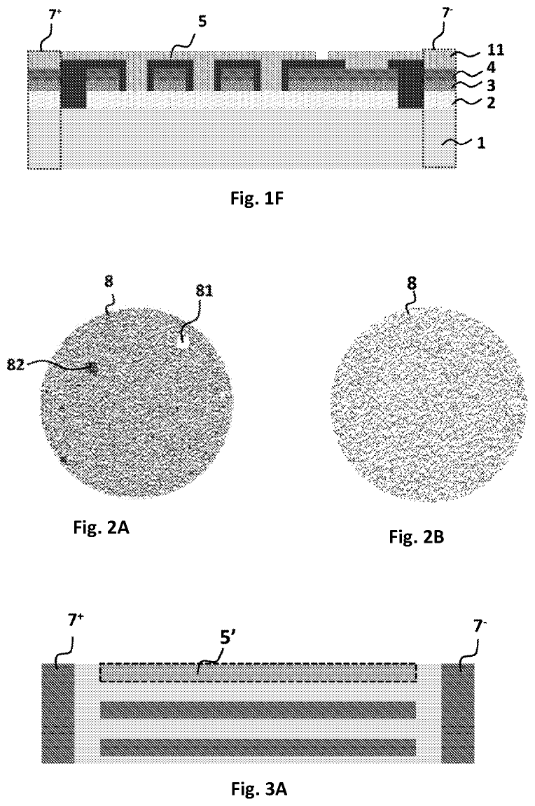

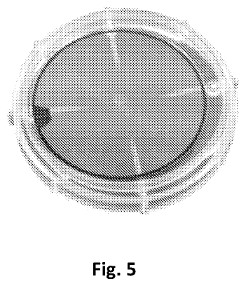

The invention will now be described in greater detail with the aid of a description of FIGS. 1 to 5.

FIG. 1A is a sectional view of a photovoltaic stack that is known from the prior art. In this example, the stack is composed of:
a glass substrate (1);
a front electrode (2) that is formed from a transparent conductive oxide, for example zinc oxide doped with aluminum (ZnO:Al) or tin oxide doped with fluorine (SnO₂:F);
an absorber (3) that is composed of a plurality of layers based on amorphous silicon (a_Si) forming a junction p-i-n;
a rear electrode (4) that is formed from one or more metals or metal alloys, for example aluminum or silver.

It is possible to transform this stack by photolithographic etching and deposition methods that are known to those skilled in the art in order to obtain a semitransparent photovoltaic module. The first step of this process is to create the transparency areas (6_{T}) and to electrically isolate the collection buses (7+, 7−) by means of isolation areas (6_{I}). Transparency and isolation areas (6_{T} and 6_{I}) are produced through successive etching of the thin layers, forming the rear electrode, the absorber, and the front electrode.

FIG. 1B is a top view of semitransparent photovoltaic cells with transparent areas (6T) that have the shape of horizontal strips parallel to each other, are of the critical dimension CDT, and separate the opaque active photovoltaic areas (5) of critical dimension CD_{PV} two by two. The vertical opaque strips are the collection buses (7⁺ and 7⁻), which are electrically isolated from the active photovoltaic areas (5).

Transparency areas (6_{T}) electrically isolate the active photovoltaic strips (5), with each of said strips forming unit photovoltaic cells. In order to electrically connect (in series and/or in parallel) these isolated active photovoltaic areas to the collection buses (7⁺ and 7⁻) to obtain a photovoltaic module, it is necessary to establish an electrical contact between the conductive transparent oxide (2) and one of the collection buses (7⁺). This electrical contact is established by means of a metal collection grid that is electrically isolated from the rear electrode through the use of an isolating material, generally a polymer. The collection grid described in the rest of the document is formed by:
a metallic contact layer (11);
a multitude of contacts between the front electrode and the metallic contact layer, called VIAs (8).

Establishing a VIA-type contact comprises a plurality of consecutive steps. Let us consider the example of an architecture consisting of semitransparent strips such as that shown in FIG. 1B.

Step 1: Contact areas (80) are etched within the active photovoltaic areas (5). In the example of FIG. 1C, these contact areas (80) are square in shape and perfectly included within the active photovoltaic strips (5). Two neighboring contact areas (80) within the same active photovoltaic area (5) are separated by an inter-VIA distance (D_{VIA}). The ends of the active photovoltaic area (Ex⁺, Ex⁻, respectively) are defined as the edges adjacent to the isolation areas (6_{I+}, 6_{I-}, respectively). The distance between an end (Ex⁺, Ex⁻, respectively) is called the inter-VIA-end distance D_{EX} (D_{EX+}, D_{EX-}, respectively).

The contact areas (80) result from the etching of the rear electrode (4) and of the absorber layer (3) by means of conventional photolithography methods that are known to those skilled in the art. FIG. 1D is a sectional view of FIG. 1C along the direction X where the VIA-type contact areas (80) appear.

Step 2: An electrically isolating layer (9) is introduced in order to electrically isolate the front electrode (2) from the rear electrode (4). FIG. 1E is a sectional view taken from FIG. 1D to which the isolation layer (9) has been added. This electrically isolating layer is a transparent, permanent, and photosensitive resin, for example. The VIA-type contact areas (80′) are left vacant in order to achieve contact on the conductive transparent oxide (2), the object of which is to improve the collection of the photogenerated electric charges within the active photovoltaic areas. Rear contact areas (10) are left vacant in order to achieve contact on the metal (4).

Step 3: A metallic contact layer (11) is then deposited and etched, for example using a new photolithography step as shown in FIG. 1F, in order to connect the front electrode (2) to the 7⁺ bus and the rear electrode (4) to the bus 7⁻, all with the purpose of making the semitransparent photovoltaic module functional.

The area of a VIA is defined as being the contact area between the contact metal (11) and the front electrode (2). This surface can be of any shape.

The invention aims to optimize the placement of VIAs (8) within a semitransparent photovoltaic device. This optimization takes into account both the electrical aspects and the visual rendering of semitransparent photovoltaic modules. In order to maximize the electrical performance of said photovoltaic modules, the inter-VIA (D_{VIA}) and inter-VIA-end distance (D_{EX}) is between 1 μm and 1000 μm.

FIG. 2A is an illustration of the visual rendering of VIAs produced according to the prior art and placed randomly and creating visual defects for a semitransparent photovoltaic module that is intended to be integrated into a watch glass. The random placement of VIAs follows the following constraints:
a VIA can only be placed within active photovoltaic areas;
the inter-VIA and inter-VIA-end distances are between 5 μm and 1000 μm. Without additional constraints, a random placement can generate:
VIA clusters (82), corresponding to a high concentration density of VIAs for a given reference surface (S_{ref}), appearing as a dark spot to the naked eye in photovoltaic devices;
VIA gaps (81), corresponding to a low concentration density of VIAs for a given reference surface (S_{ref}), as a light spot to the naked eye in photovoltaic devices.

The invention should make it possible to eliminate the appearance of VIA clusters (82) and gaps (81). It is considered that the elimination of clusters (82) is made possible if the density of the VIAs remains less than 70 VIAs/mm² everywhere. The elimination of gaps (81) is made possible if the density of the VIAs remains greater than 10 VIAs/mm² everywhere.

FIG. 2B is an illustration of the visual rendering of VIAs that have been placed randomly but following the constraints set out above, which eliminates the visual defects for a semitransparent photovoltaic module according to the invention that is intended to be integrated into a watch glass. Indeed, the integration of these architectural constraints of placement makes it possible to eliminate the appearance of VIA clusters and gaps that are harmful from a visual standpoint.

Consider a semitransparent strip-type module as shown in FIG. 1B. A method for random placement of the VIAs that enables the manufacture of the semitransparent device according to the invention follows steps A to F described below.

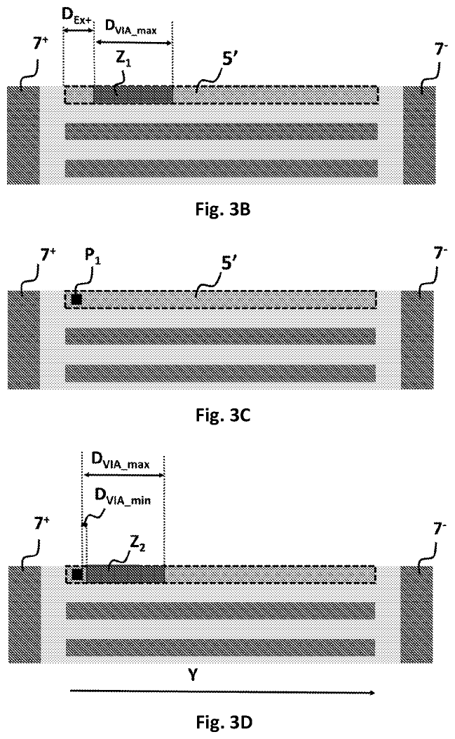

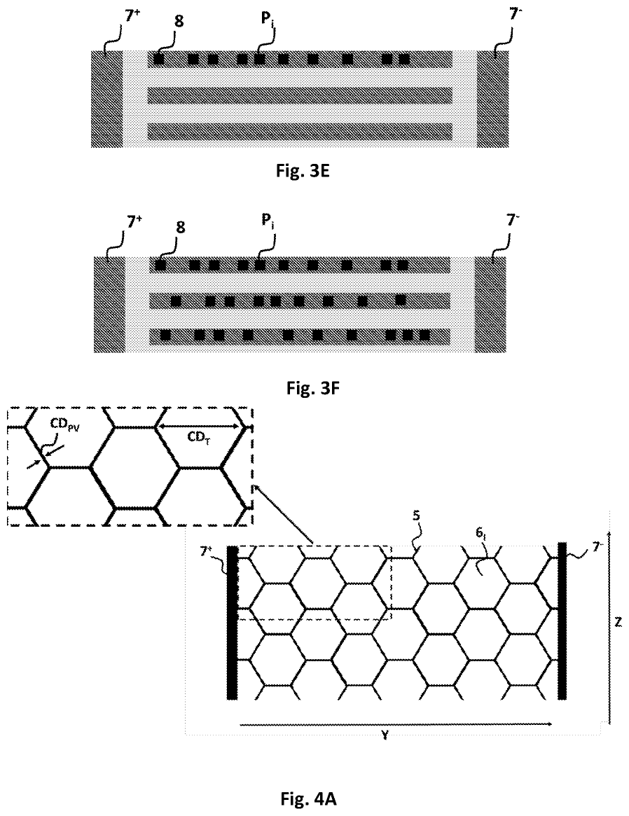

Step A: Selection of an eligible active photovoltaic area for the placement of VIAs, which is broken down into sub-steps as follows:
Step A1: Selection of an active photovoltaic area (5′) without a VIA that was not already selected previously
   This selection can be made arbitrarily. However, it is recommended to start with one edge of the device. In this example, it is possible to start with the top edge of the device as described in FIG. 3A. In this example, the first active photovoltaic area selected is therefore the area 5′.
Step A2: Selection of eligibility criteria for active photovoltaic areas for VIA placement.
   For reasons of the size of active photovoltaic areas, it is sometimes desirable not to retain photovoltaic areas for the placement of VIAs.
Step A3: Validation of the selection for the placement of the VIAs in this area, for example according to the VIAS already present in the device or according to constraints of the particular geometry of the device (for example, the presence of a watch flange in the case of a screen for a photovoltaic watch).
   Said area will then be referred to as the eligible active photovoltaic area.

Step B: Define the constraints for the placement of VIAs (8)
D_{VIA_min}=5 μm
D_{VIA_max}=1000 μm
10<d<70 VIAs/mm²

Step C: Initialization of the placement of VIAs (8) within the eligible active photovoltaic areas, which breaks down into sub-steps as follows:
Step C0: Selection of the end of the eligible active photovoltaic area (5′), namely Ex⁺ in the example of FIG. 3B, and its value is defined according to D_{EX+}=D_{VIA_min_0}=5 μm.
Step C1: Selection of the first VIA placement area (8), Z₁, which is determined by the inter-VIA-end distance D_{Ex+}and the maximum inter-VIA distance D_{VIA_max}. The first placement area is therefore included between D_{EX+} and (D_{EX+}+D_{VIA_max}).
Step C2: Random placement P₁ of the first VIA (8) in the first VIA placement area Z₁. An example of such a placement is shown in FIG. 3C.

Step D: Iterative method for the placement of other VIAs (8)
Step D1: Let us take the example of the case of the area Z₂. According to the direction Y, the area Z₂ extends from the distance D_{VIA_min} to the distance D_{VIA_max} from the first VIA placed at P₁, as shown in FIG. 3D.
Step D2: For example, the placement P₂ is randomly placed within area Z₂ of FIG. 3D.
The iterative process of step D ends when all of the VIAs (8) have been placed in the eligible active photovoltaic area (5) selected in step A. An example is shown in FIG. 3E.

Step E: Return to step A as long as one or more active photovoltaic area(s) not already selected previously does not contain VIAs. An example is shown in FIG. 3F.

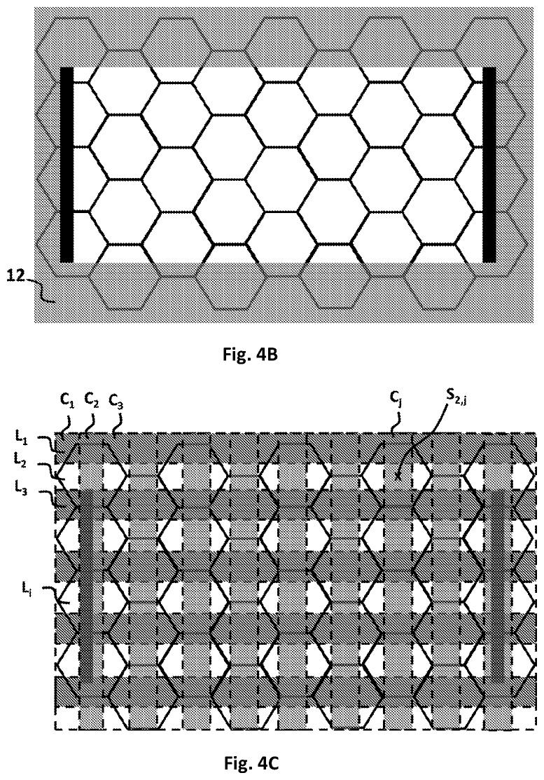

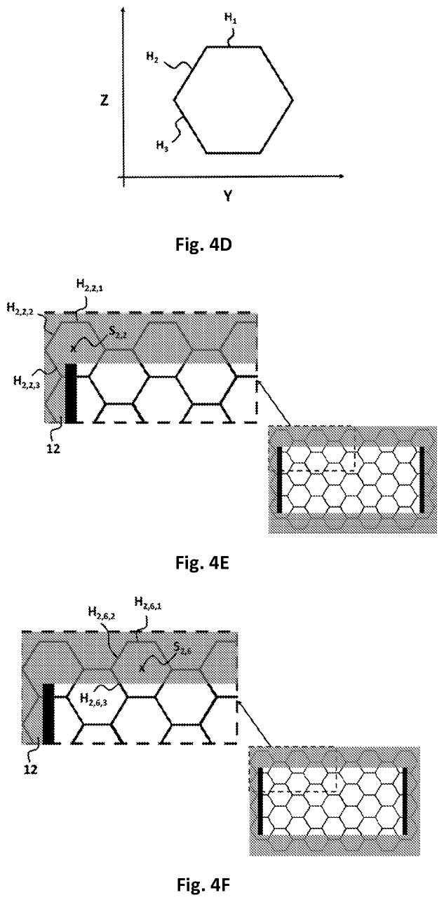

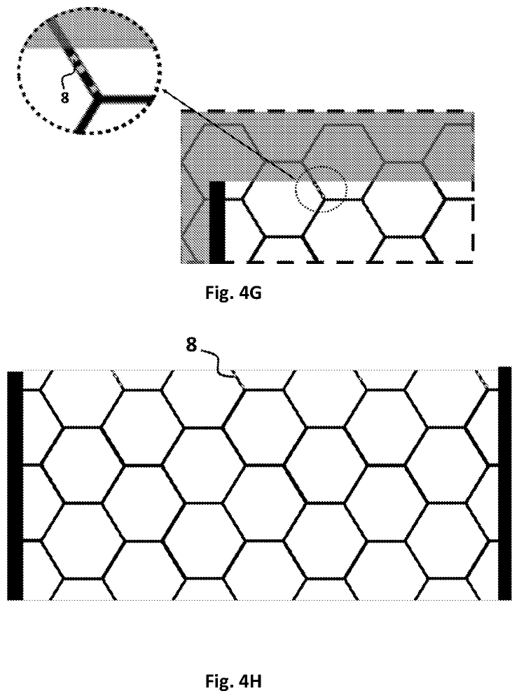

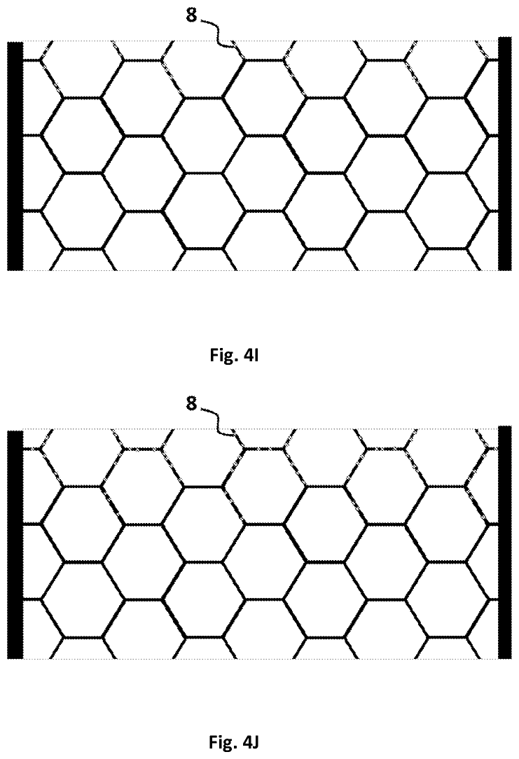

Let us consider a semitransparent module whose transparency areas form hexagons arranged in a “honeycomb”-type network. FIG. 4A shows such a module. For greater clarity, the isolation areas have not been shown. Transparency areas (6_{T}) therefore have the shape of all or part of a hexagon of the critical dimension CD_{T} as described in the zoom of FIG. 4A, separating opaque active photovoltaic areas (5) of the critical dimension CD_{PV}. The description of the device is given along the Y and Z axes as described in FIG. 4A. Preferably, the Y axis is selected so as to be perpendicular to the collection bus, and its orientation is selected arbitrarily from one bus to another, here from the bus 7⁺ to the bus 7⁻. The Z axis is advantageously perpendicular to the Y axis and directed toward the top of the device.

In order to place the VIAs using the method described above, it is necessary to select the photovoltaic areas. Considering a continuous photovoltaic line going from one bus to the other of the device does not allow all of the photovoltaic areas to be traversed. In this example, it is then desirable to define an active photovoltaic area as a photovoltaic segment that forms one of the sides of the hexagon and within which steps A2, A3, B, C and D will be carried out. Since these steps are identical to those presented in the example of the semitransparent strip-type photovoltaic module, they will not be detailed again below.

A method for selecting all of the photovoltaic segments of the device is proposed below.

Step 1: Artificial reconstruction of incomplete hexagons in order to allow the indexing of the hexagons and the selection of the sides thereof, thus enabling steps 2, 3, and 4 to be carried out.

FIG. 4B shows the device of FIG. 4A within which the incomplete hexagons have been artificially completed. The gray areas (12) therefore do not form part of said device.

Step 2: Indexing of the hexagons

In this step, it is recommended to use a row (Lᵢ) and column (Cⱼ) mesh in order to be able to identify the hexagons. Advantageously, the hexagons of index i,j can be selected by their center S_{i,j}. A regular mesh is proposed within FIG. 4C which makes it possible to uniquely index each hexagon by its center S_{i,j}. The hexagon of the index (2,j) is selected via its center S_{2,j}.

Let M denote the number of rows and N the number of columns of said mesh. In the example of FIG. 4C, M=10 and N=19.

It should be noted that, in this mesh, the hexagons are described by the following centers:
S_{i,j} such that i=2k, k varying from 1 to ((M/2)−1) and j=4L+2, L variant from 0 to ((N+1)/5−1);
S_{i,j} such that i=2k+1, k varying from 1 to ((M/2)−1) and j=4L, L varying from 1 to ((N+1)/5−1);

Step 3: Selection of three adjacent sides H₁, H₂, H₃ of any hexagon according to the orientation of FIG. 4A.

In order to select all of the photovoltaic segments of the real device, it is sufficient for each hexagon of FIG. 4C for the same three sides to be selected for all hexagons. The selection of these sides can be done in a completely arbitrary manner without consequence. For example, the three sides Hᵢ are selected according to the representation of FIG. 4D. Hᵢ corresponds to the horizontal segment having the highest ordinate Z. H₂ represents the segment having an end in common with H₁, said end of which is common to the smallest abscissa (in this example, to the left of H₁). The side H₃ is the side adjacent to the second end of H₂.

Step 4: Selection of photovoltaic areas and placement of VIAs

For i varying from 1 to N
For j varying from 1 to M
Step 4A: Selecting the hexagon having the center S_{i,j}

For k varying from 1 to 3

Step 4B: Selection of the side H_{i,j,k} and definition of the eligible photovoltaic area
If H_{i,j,k} belongs to a gray area of the description, this side does not belong to the device; return to step 4B or 4A if all of the sides of the central hexagon S_{i,j} have been considered
If H_{i,j,k} partially belongs to the device, the active photovoltaic area corresponds to the segment contained in H_{i,j,k} belonging to the device; proceed to step 4C for said photovoltaic area.
If H_{i,j,k} fully belongs to the device, the eligible active photovoltaic area corresponds to the entire side H_{i,j,k}.

Step 4C: Perform steps A2, A3, B, C, and D

Repeat step 4 until all hexagons have been considered.

In order to better understand these steps, let us consider the example of FIG. 4D.
The first hexagon to be considered, having the center S_{2,2}, is shown in FIG. 4E. The three segments H_{2,2,1} H_{2,2,2,} and H_{2,2,3} do not belong to the device. Step 4C is not applied.
The second hexagon to be considered, having the center S_{2.6}, is shown in FIG. 4F. Both sides H_{2,6,1} and H_{2,6,2} do not belong to the device. Step 4C is not applied. On the other hand, part of the segment H_{2,6,3} belongs to the device. Step 4C is applied to the active photovoltaic area belonging to the side H_{2,6,3} and to the device. An example of the placement of vias 8 is shown in FIG. 4G.
After having considered all of the centers having the index i=2, an example of the placement of VIAs is given in FIG. 4H.

Let us now consider the index i=3. The hexagons to be considered have the centers S_{3,4}, S_{3,8}, S_{3,12}, and S_{3,16}. By applying the algorithm to this entire row, we obtain the results of FIG. 4I, for example, with regard to the placement of the vias.

Now let us consider the index i=4. The hexagons to be considered have the centers S_{4,2}, S_{4,6}, S_{4,10}, S_{4,44,} and S_{4,}18. By applying the algorithm to this entire row, we obtain the results of FIG. 4J, for example.

After having gone through all of the values of i and j, all of the photovoltaic segments will have been processed and the placement of the vias carried out.

This example of an algorithm for the placement of VIAs within a honeycomb structure is not limiting and is presented only by way of example. Those skilled in the art will know how to generate the appropriate algorithms as a function of the transparency patterns.

| | |
|---|---|
| 1 | Substrate |
| 2 | Front electrode |
| 3 | Absorber |
| 4 | Rear electrode |
| 5 | Active photovoltaic areas |
| 6_{T} | Transparency areas |
| 6_{I} | Isolation area |
| 7⁺, 7⁻ | Collection bus |
| 8 | VIA |
| 80 | Contact area |
| 81 | VIA gaps |
| 82 | VIA clusters |
| 9 | Isolation layer |
| 10 | Metal/metal contact area |
| 11 | Metallic contact layer |
| 12 | Gray areas from the description not belonging |
| | to the photovoltaic device |
| Zᵢ | Effective VIA placement area |
| Pᵢ | VIA placement area |
| CDₚᵥ | Critical dimension of photovoltaic areas |
| CD_{T} | Critical dimension of the transparency area |
| S_{i,j} | Center of hexagon of index i, j |

### Exemplary Embodiment

A plurality of semitransparent thin-film photovoltaic devices according to the invention were produced. Let us take the concrete example of a semitransparent photovoltaic module that is designed to be integrated into a watch glass. This module comprises:
A transparent substrate (1) made of soda-lime glass;
A front electrode (2) made of zinc oxide doped with aluminum (ZnO:Al);
An absorber (3) composed essentially of amorphous silicon (aSi);
A rear metal electrode (4) made of aluminum;
two collection buses (7⁺, 7⁻);
an electrically isolating layer (9) of acrylic resin;
a metallic contact layer (11) made of aluminum;
VIAs (8), the area S of which is 20 μm²;
transparency areas (6T) that are hexagonal in shape and have a critical dimension CD_{T} of 285 μm;
active photovoltaic areas (5) whose critical dimension CD_{PV} is 14 μm.

This photovoltaic module has a diameter of 35 mm. It has a transparency level of 90%. In view of the dimensions involved, the VIAs were placed entirely within the photovoltaic areas. The placement of the VIAs was performed randomly under constraints such as:
the maximum distance Dₘₐₓ between two VIAs is equal to 800 μm;
the minimum distance Dₘᵢₙ between two VIAs is equal to 10 μm;
the density d of the VIAs is less than 20 VIAs/mm²;

A Gaussian random distribution was used for the placement of VIAs in the effective VIA placement areas.

A photograph of said exemplary embodiment is shown in FIG. 4.

1. A semitransparent photovoltaic device, comprising:
a plurality of active photovoltaic areas including—
a transparent substrate,
a front electrode,
an absorber including one or more thin photoactive layers, and
a rear electrode;
a transparency area separating at least two of the active photovoltaic areas; and
a collection grid including—
a metallic contact layer, and
a plurality of VIAs between the front electrode and the metallic contact layer, wherein the VIAs are randomly distributed within the active photovoltaic area.

2. The semitransparent photovoltaic device of claim 1, wherein the critical dimension CDPv of the active photovoltaic areas is between 1 μm and 100 μm.

3. The semitransparent photovoltaic device of claim 1, wherein the critical dimension CDT of the transparency area is less than 1 mm.

4. The semitransparent photovoltaic device of claim 1, wherein the surface area of a first one of the VIAs is between 15 μm² and 50 μm².

5. The semitransparent photovoltaic device of claim 1, wherein the maximum distance D_{VIA_max} between two VIAs is about 1000 μm.

6. The semitransparent photovoltaic device of claim 1, wherein the minimum distance D_{VIA_min} between two VIAs is about to 5 μm.

7. The semitransparent photovoltaic device of claim 1, wherein the density d of the VIAs is less than 70 VIAs/mm².

8. The semitransparent photovoltaic device of claim 1, wherein the density of the VIAs is greater than 10 VIAs/mm².

9. The semitransparent photovoltaic device of claim 1, wherein all of the VIAs are centered within the active photovoltaic areas.

10. The semitransparent photovoltaic device of claim 1, wherein at least one of the photoactive layers of the absorber is composed of amorphous silicon.
